(19) United States
(12) Patent Application Publication
(10) Pub. No.: US 2026/0324371 A1
(43) Pub. Date: Oct. 15, 2026

(54) SUBSTRATE PROCESSING METHOD AND SUBSTRATE PROCESSING SYSTEM

(71) Applicant: Tokyo Electron Limited, Tokyo (JP)

(72) Inventors: Yohei YAMASHITA, Kikuchi-gun, Kumamoto (JP); Hirotoshi MORI, Tokyo (JP); Yosuke NAKAMURA, Kikuchi-gun, Kumamoto (JP); Kazuhiro SHIBA, Kikuchi-gun, Kumamoto (JP); Kazuya IWANAGA, Kikuchi-gun, Kumamoto (JP); Kazuya HISANO, Koshi City, Kumamoto (JP)

(21) Appl. No.: 19/116,513

(22) PCT Filed: Aug. 17, 2023
(86) PCT No.: PCT/JP2023/029716

§ 371 Date: Mar. 28, 2025

(30) Foreign Application Priority Data
Sep. 30, 2022 (JP) 2022-158103

(51) Int. Cl. H10P 90/00; H10P 54/20; H10P 72/00

(52) U.S. Cl. CPC H10P 90/128; H10P 54/20; H10P 72/0428; H10P 72/0604; H10P 72/0606

(57) ABSTRACT

A substrate processing method of processing a combined substrate in which a first substrate and a second substrate are bonded is provided. The first substrate includes: a notch formed by cutting out a part of a peripheral portion of the first substrate to be removed; a bonding portion bonded to the second substrate; and a non-bonding portion not bonded to the second substrate. The substrate processing method includes: forming a peripheral modification layer by radiating laser light along a boundary between the peripheral portion of the first substrate and a central portion of the first substrate; and separating the peripheral portion from the combined substrate, starting from the peripheral modification layer. In the forming of the peripheral modification layer, a formation position of the peripheral modification layer corresponding to a portion where the notch is formed is determined based on information of the non-bonding portion.

### TECHNICAL FIELD

The various aspects and embodiments described herein pertain generally to a substrate processing method and a substrate processing system.

### BACKGROUND

Patent Document 1 describes a substrate processing system that processes a combined substrate in which a first substrate and a second substrate are bonded to each other. The substrate processing system described in Patent Document 1 includes an interface processing apparatus configured to perform a processing on a bonding interface between the first substrate and the second substrate at a peripheral portion of the first substrate, which is a target to be removed; a modification layer forming apparatus configured to form a modification layer inside the first substrate along a boundary between the peripheral portion and a central portion of the first substrate; and a periphery removing apparatus configured to remove the peripheral portion of the first substrate, starting from the modification layer.

### PRIOR ART DOCUMENT

Patent Document 1: Japanese Patent Laid-open Publication No. 2022-097506

### DISCLOSURE OF THE INVENTION

### Problems to be Solved by the Invention

Exemplary embodiments provide a technique capable of appropriately removing, in a combined substrate in which a first substrate and a second substrate are bonded to each other, a peripheral portion of the first substrate, taking into account a non-bonding region at a notch portion formed at the first substrate.

### Means for Solving the Problems

In an exemplary embodiment, there is provided a substrate processing method of processing a combined substrate in which a first substrate and a second substrate are bonded. The first substrate includes: a notch formed by cutting out a part of a peripheral portion of the first substrate to be removed; a bonding portion bonded to the second substrate; and a non-bonding portion not bonded to the second substrate. The substrate processing method includes: forming a peripheral modification layer serving as a starting point for separation of the peripheral portion by radiating laser light along a boundary between the peripheral portion of the first substrate and a central portion of the first substrate; and separating the peripheral portion from the combined substrate, starting from the peripheral modification layer. In the forming of the peripheral modification layer, a formation position of the peripheral modification layer corresponding to a portion where the notch is formed is determined based on information of the non-bonding portion.

### Effect of the Invention

According to the exemplary embodiments, it is possible to appropriately remove, in the combined substrate in which the first substrate and the second substrate are bonded to each other, the peripheral portion of the first substrate, taking into account the non-bonding region at the notch portion formed at the first substrate.

### BRIEF DESCRIPTION OF THE DRAWINGS

FIG. 1 is an enlarged side view illustrating an example structure of a combined wafer according to an exemplary embodiment.

FIG. 2 is an explanatory plan view illustrating the example structure of the combined wafer according to the exemplary embodiment.

FIG. 3 is an explanatory side view illustrating the example structure of the combined wafer according to the exemplary embodiment.

FIG. 4 is a plan view schematically illustrating a configuration example of a wafer processing system according to the exemplary embodiment.

FIG. 5 is a plan view illustrating a configuration example of an interface modifying apparatus and an internal modifying apparatus.

FIG. 6 is a side view illustrating the configuration example of the interface modifying apparatus and the internal modifying apparatus.

FIG. 7A to FIG. 7D are explanatory diagrams illustrating main processes of a wafer processing according to the exemplary embodiment.

FIG. 8 is a flowchart illustrating main processes for forming a peripheral modification layer according to the exemplary embodiment.

FIG. 9 is a graph showing a relationship between a circumferential position of the combined wafer and an eccentric amount.

FIG. 10 is an explanatory diagram illustrating a peripheral modification layer formed by a conventional method.

FIG. 11 is an explanatory diagram illustrating a peripheral modification layer formed by a first pattern according to the exemplary embodiment.

FIG. 12 is an explanatory diagram illustrating the peripheral modification layer formed by the first pattern according to the exemplary embodiment.

FIG. 13 is an explanatory diagram illustrating a peripheral modification layer formed by a second pattern according to the exemplary embodiment.

FIG. 14 is an explanatory diagram illustrating a peripheral modification layer formed by a third pattern according to the exemplary embodiment.

FIG. 15 is an explanatory diagram illustrating another example of the peripheral modification layer formed by the third pattern according to the exemplary embodiment.

FIG. 16 is an explanatory diagram illustrating yet another example of the peripheral modification layer formed by the third pattern according to the exemplary embodiment.

FIG. 17 is an explanatory diagram illustrating still yet another example of the peripheral modification layer formed by the third pattern according to the exemplary embodiment.

FIG. 18 is an explanatory diagram illustrating still yet another example of the peripheral modification layer formed by the third pattern according to the exemplary embodiment.

FIG. 19 is an explanatory diagram illustrating still yet another example of the peripheral modification layer formed by the third pattern according to the exemplary embodiment.

FIG. 20 is an explanatory diagram illustrating still yet another example of the peripheral modification layer formed by the third pattern according to the exemplary embodiment.

FIG. 21 is a graph showing a relationship between a circumferential position of the combined wafer and an amount of eccentricity used in processing the combined wafer in the third pattern according to the exemplary embodiment.

FIG. 22 is an explanatory diagram illustrating an example method of forming the peripheral modification layer by the third pattern according to the exemplary embodiment.

FIG. 23 is an explanatory diagram illustrating the example method of forming the peripheral modification layer by the third pattern according to the exemplary embodiment.

FIG. 24A and FIG. 24B are explanatory diagrams showing a result of performing an averaging processing on the relationship between the circumferential position of the combined wafer and the eccentric amount.

FIG. 25 is an explanatory diagram illustrating crystal orientation of the first wafer.

### DETAILED DESCRIPTION

In a manufacturing process for a semiconductor device, in a combined wafer in which two semiconductor substrates (hereinafter, referred to as “wafers”) are bonded, removal of a peripheral portion of a first wafer having devices such as a plurality of electronic circuits formed on a front surface thereof, so-called edge trimming may be performed.

The edge trimming of the first wafer is performed by using a wafer processing system (substrate processing system) described in, for example, Patent Document 1. A modification layer is formed by radiating laser light to an inside of the first wafer (first substrate), and the peripheral portion of the first wafer is removed starting from the modification layer. Further, by performing a required processing on an interface where the first wafer and a second wafer are bonded, bonding strength at the interface between the first wafer and the second wafer is reduced to enable appropriate removal of the peripheral portion.

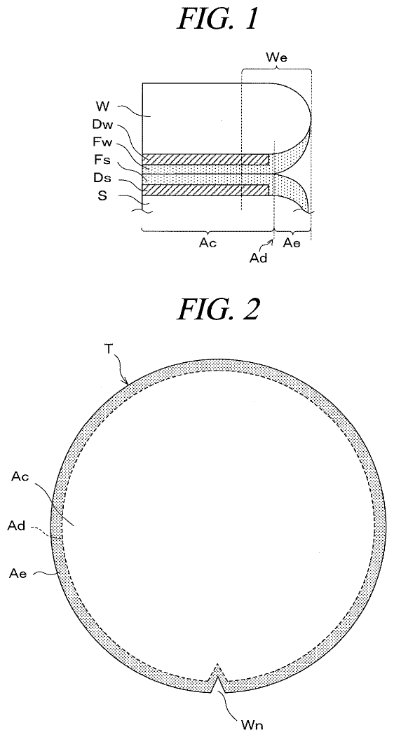

However, an end portion of the first wafer W, including a peripheral portion We as a removal target by the edge trimming, is chamfered, and the thickness of this peripheral portion We decreases toward a leading end thereof (see FIG. 1). For this reason, in the combined wafer in which the first wafer W and the second wafer S are bonded together, the first wafer W and the second wafer S are not in contact with each other and not bonded to each other at the chamfered portion with the reduced thickness. Even in a region inner than this chamfered portion in a radial direction, there may exist a region where the first wafer W and the second wafer S are not bonded due to various factors, such as a wafer processing result in a previous process or conditions at the time of bonding the first wafer W and the second wafer S, and the like.

In the following explanation, in a combined wafer T in which the first wafer W and the second wafer S are bonded to each other, a portion where the first wafer W and the second wafer S are not bonded may be referred to as “non-bonding portion,” and a portion where the first wafer W and the second wafer S are bonded may be referred to as “bonding portion.”

Further, the non-bonding portion may be formed even at an inner side than the chamfered portion of the first wafer W in the radial direction as stated above. In order to avoid too complicated explanation, the non-bonding portion corresponding to the chamfered portion may be referred to as “non-bonding region Ae,” the boning portion inside the non-bonding region Ae in the radial direction may be referred to as “bonding region Ac,” and a boundary portion between the non-bonding region Ae and the bonding region Ac may be referred to as “boundary Ad,” as illustrated in FIG. 1 and FIG. 2.

Since the first wafer W and the second wafer S are not bonded in the non-bonding region Ae, if the edge trimming is performed in this non-bonding region Ae, the first wafer W may be spaced apart from the second wafer S at the interface of the combined wafer T after being subjected to the edge trimming, which may cause chipping in a subsequent process.

Here, a notch Wn for indicating the direction of crystal orientation is formed at the peripheral portion We of the first wafer W, which is a semiconductor substrate, inwards in the radial direction from an outer end of the first wafer W. In this portion where the notch Wn is formed, since a non-bonding portion is formed along the notch Wn when viewed from the top as shown in FIG. 2, the non-bonding region Ae is formed up to an inner side in the radial direction, as compared to a portion where the notch Wn is not formed. For this reason, when a certain trim width is set from the outer end of the wafer where no notch Wn exists, the edge trimming may be performed at the non-bonding portion in the portion where the notch Wn is formed, and the first wafer W may be spaced apart from the second wafer S, which may cause chipping in a subsequent process.

In view of the foregoing, exemplary embodiments of the present disclosure provide a technique enabling appropriate removal of a peripheral portion of a first substrate in a combined substrate in which the first substrate and a second substrate are bonded to each other, taking into account a non-bonding region in a notch portion formed in the first substrate. Hereinafter, a wafer processing system as a substrate processing system and a wafer processing method as a substrate processing method according to an exemplary embodiment will be described with reference to the accompanying drawings. In the present specification and the drawings, parts having substantially the same functions and configurations will be assigned same reference numerals, and redundant descriptions thereof will be omitted.

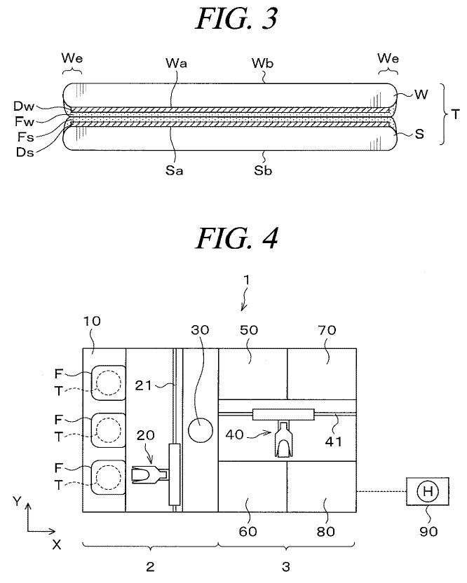

In a wafer processing system 1 to be described later according to the present exemplary embodiment, a processing is performed on a combined wafer T as a combined substrate in which a first wafer W as a first substrate and a second wafer S as a second substrate are bonded to each other as shown in FIG. 1 and FIG. 3. Hereinafter, in the first wafer W, a surface bonded to the second wafer S is referred to as a front surface Wa, and a surface opposite to the front surface Wa is referred to as a rear surface Wb. Likewise, in the second wafer S, a surface bonded to the first wafer W is referred to as a front surface Sa, and a surface opposite to the front surface Sa is referred to as a rear surface Sb.

The first wafer W is, for example, a semiconductor substrate such as a silicon substrate, and a device layer Dw including a plurality of devices is formed on the front surface Wa thereof. Further, a bonding film Fw is further formed on the device layer Dw, and the first wafer W is bonded to the second wafer S with the bonding film Fw therebetween. An oxide film (a THOX film, a SiO₂ film, a TEOS film, etc.), a SiC film, a SiCN film, or an adhesive is used as an example of the bonding film Fw. Further, as illustrated in FIG. 1, a peripheral portion We of the first wafer W is chamfered, and the thickness of this peripheral portion We decreases toward a leading end thereof on a cross section thereof. Furthermore, the peripheral portion We is a portion to be removed in edge trimming to be described later, and is in the range of 0.5 mm to 3 mm from an edge of the first wafer W in a radial direction.

Further, as illustrated in FIG. 2, the notch Wn indicating crystal orientation is formed at the peripheral portion We of the first wafer W. In one example, the notch Wn is formed by cutting out a part of the outer end of the first wafer W. The shape of the notch Wn is not limited to the approximate triangle shown in FIG. 2, and the notch Wn be formed to have, by way of non-limiting example, an approximately elliptical shape or an approximately circular shape.

The second wafer S has, for example, the same structure as the first wafer W. A device layer Ds and a bonding film Fs are formed on the front surface Sa, and a peripheral portion of the second wafer S is chamfered and provided with a notch. However, the second wafer S does not need to be a device wafer on which the device layer Ds is formed, but it may be, for example, a support wafer that supports the first wafer W.

As depicted in FIG. 4, the wafer processing system 1 has a configuration in which a carry-in/out station 2 and a processing station 3 are connected as one body. In the carry-in/out station 2, a FOUP F capable of accommodating therein a plurality of combined wafers T is carried to/from the outside, for example. The processing station 3 is equipped with various types of processing apparatuses configured to perform required processes on the combined wafer T.

The carry-in/out station 2 is equipped with a FOUP placement table 10 on which the FOUP F capable of accommodating therein the plurality of combined wafers T is placed. Further, a wafer transfer device 20 is provided adjacent to the FOUP placement table 10 on the positive X-axis side of the FOUP placement table 10. The wafer transfer device 20 is configured to be moved on a transfer path 21 extending in the Y-axis direction to transfer the combined wafer T between the FOUP F on the FOUP placement table 10 and a transition device 30 to be described later.

In the carry-in/out station 2, the transition device 30 configured to deliver the combined wafer T to/from the processing station 3 is provided adjacent to the wafer transfer device 20 on the positive X-axis side of the wafer transfer device 20.

Disposed in the processing station 3 are a wafer transfer device 40, an interface modifying apparatus 50, an internal modifying apparatus 60, a periphery removing apparatus 70, and a cleaning apparatus 80.

The wafer transfer device 40 is provided on the positive X-axis side of the transition device 30. The wafer transfer device 40 is configured to be movable on a transfer path 41 extending in the X-axis direction to transfer the combined wafer T to/from the transition device 30 of the carry-in/out station 2, the interface modifying apparatus 50, the internal modifying apparatus 60, the periphery removing apparatus 70 and the cleaning apparatus 80.

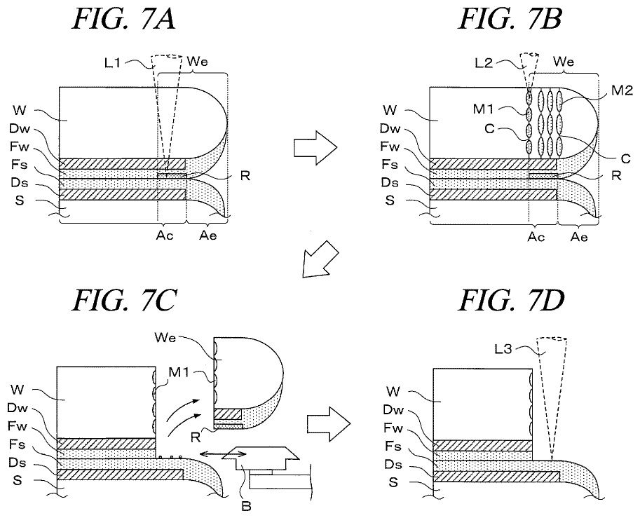

The interface modifying apparatus 50 is configured to radiate laser light (interface laser light such as a CO₂ laser) to an interface between the first wafer W and the second wafer S to form a bonding strength reduction region R (see FIG. 7A to FIG. 7D to be described later) in which bonding strength between the first wafer W and the second wafer S is reduced.

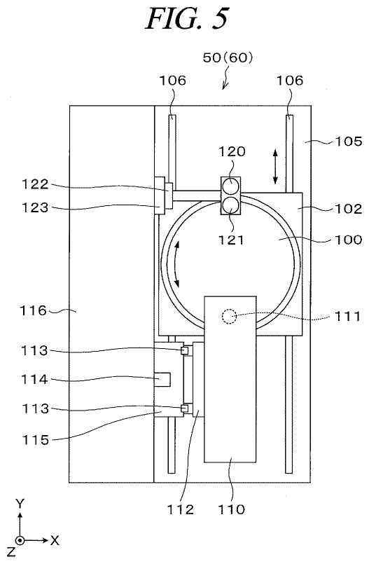

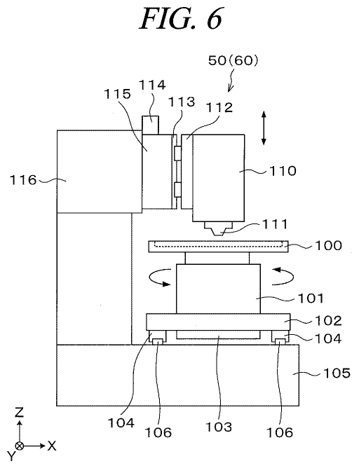

As depicted in FIG. 5 and FIG. 6, the interface modifying apparatus 50 has a chuck 100 as a substrate holder configured to hold the combined wafer T on a top surface thereof. The chuck 100 attracts and holds the combined wafer T. The chuck 100 may attract and hold the rear surface Wb of the first wafer W or the rear surface Sb of the second wafer S. The chuck 100 is supported by a slider table 102 with an air bearing 101 therebetween. A rotating mechanism 103 is provided on a bottom surface of the slider table 102. The rotating mechanism 103 has, for example, a motor as a driving source embedded therein. The chuck 100 is configured to be rotatable around a vertical axis by the rotating mechanism 103 via the air bearing 101. The slider table 102 is configured to be movable on a rail 106 extending on a base 105 in the Y-axis direction by a moving mechanism 104 that is provided on a bottom surface of the slider table 102. Further, although not particularly limited, a driving source of the moving mechanism 104 may be, by way of example, a linear motor.

A laser head 110 is disposed above the chuck 100. The laser head 110 has a lens 111. The lens 111 is a cylindrical member provided on a bottom surface of the laser head 110, and is configured to radiate the interface laser light as second laser light to an inside of the combined wafer T held by the chuck 100, more specifically, to the interface between the first wafer W and the second wafer S. As a result, the inside portion of the combined wafer T irradiated with the interface laser light is modified, so that the bonding strength reduction region R in which the bonding strength between the first wafer W and the second wafer S is reduced is formed. In the technology according to the present disclosure, the laser head 110 and the lens 111 may sometimes be collectively referred to as “laser radiating device.”The laser head 110 is supported by a supporting member 112. The laser head 110 is configured to be movable up and down by an elevating mechanism 114 along a rail 113 extending in a vertical direction. Further, the laser head 110 is also configured to be movable in the Y-axis direction by a moving mechanism 115. Each of the elevating mechanism 114 and the moving mechanism 115 is supported on a supporting column 116.

Above the chuck 100, a macro camera 120 and a micro camera 121 are disposed on the positive Y-axis side of the laser head 110. For example, the macro camera 120 and the micro camera 121 are configured as one body, and the macro camera 120 is disposed on the positive Y-axis side of the micro camera 121. The macro camera 120 and the micro camera 121 are configured to be movable up and down by an elevating mechanism 122, and are also configured to be movable in the Y-axis direction by a moving mechanism 123. In addition, in the technology according to the present disclosure, the macro camera 120 and the micro camera 121 may sometimes be collectively referred to as “camera.”

The macro camera 120 is configured to image an outer end of the first wafer W (combined wafer T). As an example, the image taken by the macro camera 120 is used to align the first wafer W, which will be described later. The macro camera 120 has, for example, a coaxial lens, radiates infrared light (IR), and receives reflection light from a target object. The macro camera 120 has an imaging magnification of, e.g., 2 times.

The micro camera 121 is configured to image the peripheral portion We of the first wafer W and the boundary Ad between the bonding region Ac and the non-bonding region Ae. The image taken by the micro camera 121 is used to, for example, determine a radiation position of the interface laser light. The micro camera 121 is equipped with, by way of example, a coaxial lens, radiates infrared light (IR light) 8, and receives reflection light from a target object. The micro camera 121 has an imaging magnification of, e.g., 10 times, a field of view of about ⅕ of that of the macro camera 120, and a pixel size of about ⅕ of that of the macro camera 120.

In the shown example, the two cameras, that is, the macro camera 120 and the micro camera 121 are arranged, but the number of the cameras of the interface modifying apparatus 50 is not limited thereto, and one or more cameras may be arranged in the interface modifying apparatus 50 as required. By way of example, when there is no need to image the boundary Ad, such as in a case where the boundary Ad between the bonding region Ac and the non-bonding region Ae is known in advance, the micro camera 121 may be omitted.

Moreover, in the shown example, the chuck 100 is configured to be rotated and horizontally moved relative to the laser head 110 by the rotating mechanism 103 and the moving mechanism 104. However, the laser head 110 may be configured to be rotated and horizontally moved relative to the chuck 100. Still alternatively, both the chuck 100 and the laser head 110 may be configured to be rotatable and horizontally movable relative to each other.

The internal modifying apparatus 60 is configured to radiate laser light (internal laser light such as a YAG laser) to an inside of the first wafer W to form a peripheral modification layer M1 serving as a starting point for separation of the peripheral portion We and a split modification layer M2 serving as a starting point for breaking the peripheral portion We into smaller pieces. The configuration of the internal modifying apparatus 60 is not particularly limited. As an example, the internal modifying apparatus 60 has the same configuration as the interface modifying apparatus 50, as shown in FIG. 5 and FIG. 6. That is, the internal modifying apparatus 60 includes the chuck 100 configured to hold the combined wafer T on the top surface thereof, the rotating mechanism 103 configured to rotate the chuck 100 and the combined wafer T (first wafer W) relative to each other, the moving mechanism 104 configured to horizontally move the chuck 100 and the combined wafer T (first wafer W) relative to each other, the laser radiating device (laser head and lens) configured to radiate the internal laser light to an inside of the first wafer W held by the chuck 100, and the camera configured to image the combined wafer T held by the chuck 100.

Further, in the shown example, the interface modifying apparatus 50 and the internal modifying apparatus 60 are independently provided inside the wafer processing system 1. However, the interface modifying apparatus 50 and the internal modifying apparatus 60 may be configured as one body. In other words, the wafer processing system 1 may be equipped with only one modifying apparatus (not shown) and configured to be able to radiate both interface laser light and internal laser light while switching them, by using a laser radiating device belonging to the one modifying apparatus.

The periphery removing apparatus 70 is configured to perform the removal of the peripheral portion We of the first wafer W starting from the peripheral modification layer M1 formed in the internal modifying apparatus 60, that is, the edge trimming. The way to perform the edge trimming is not particularly limited. As an example, in the periphery removing apparatus 70, a blade formed in a wedge shape, for example, may be inserted into the interface between the first wafer W and the second wafer S. As another example, air or a water jet may be blown toward the peripheral portion We to apply an impact to the peripheral portion We.

The cleaning apparatus 80 is configured to perform a cleaning processing on the first wafer W and the second wafer S after being subjected to the edge trimming in the periphery removing apparatus 70 to remove particles on these wafers. A method of the cleaning is not particularly limited.

The wafer processing system 1 described above is provided with a control device 90. The control device 90 is, for example, a computer, and has a program storage (not shown). The program storage stores therein a program for controlling the processing for the combined wafer T in the wafer processing system 1. In addition, the program storage also stores therein a program for controlling the operations of the driving systems including the transfer devices and the various processing apparatuses described above to implement a wafer processing to be described later in the wafer processing system 1. The programs may have been recorded on a computer-readable recording medium H, and may be installed from the recording medium H into the control device 90. Further, the recording medium H may be transitory or non-transitory.

The wafer processing system 1 according to the present exemplary embodiment is configured as described above, but it should be noted that the configuration of the wafer processing system 1 is not limited to the shown example.

Now, a wafer processing performed by using the wafer processing system 1 configured as described in FIG. 4 will be explained. In the present exemplary embodiment, the first wafer W and the second wafer S are bonded in advance to form the combined wafer T.

First, the FOUP F accommodating therein a plurality of combined wafers T is placed on the FOUP placement table 10 of the carry-in/out station 2.

Then, the combined wafer T is taken out from the FOUP F by the wafer transfer device 20, and transferred to the interface modifying apparatus 50 via the transition device 30.

In the interface modifying apparatus 50, while rotating the combined wafer T (first wafer W) and also moving it horizontally along the Y-axis direction, interface laser light L1 is radiated in pulses to an inside of the combined wafer T, specifically, to a position at the interface between the first wafer W and the second wafer S corresponding to a set trim width of the peripheral portion We from the outer end of the first wafer W. As a result, as illustrated in FIG. 7A, the interface between the first wafer W and the second wafer S (the interface between the bonding films Fw and Fs in the shown example) is modified. In the present exemplary embodiment, the modification of the bonding interface is assumed to include amorphization of the bonding film Fw at the radiation position of the interface laser light L1, separation of the interface between the first wafer W and the second wafer S, and so forth.

In the interface modifying apparatus 50, by modifying the radiation position of the interface laser light L1 at the interface between the first wafer W and the second wafer S, more specifically, the bonding portion remaining at the peripheral portion We as described above, the bonding strength reduction region R where the bonding strength between the first wafer W and the second wafer S is reduced is formed. When the peripheral portion We of the first wafer W, which is a removal target, is removed in the edge trimming to be described later, the presence of the bonding strength reduction region R enables appropriate removal of the peripheral portion We.

In addition, when the set trim width is set to the boundary Ad of the outer periphery of the first wafer W where the notch Wn is not formed, that is, when it is set to the same width as the non-bonding region Ae corresponding to the chamfered portion of the first wafer W, the process of forming the bonding strength reduction region R in the interface modifying apparatus 50 may be omitted.

Further, in FIG. 7A, it is illustrated that the rear surface Sb of the second wafer S is held by the chuck 100, and the interface laser light L1 is radiated from the rear surface Wb side of the first wafer W. However, the rear surface Wb of the first wafer W may be held by the chuck 100, and the interface laser light L1 may be radiated from the rear surface Sb side of the second wafer S.

The combined wafer T having the bonding strength reduction region R formed at the interface between the first wafer W and the second wafer S is then transferred to the internal modifying apparatus 60 by the wafer transfer device 40.

In the internal modifying apparatus 60, by radiating internal laser light L2 to an inside of the first wafer W, a peripheral modification layer M1 and a split modification layer M2 are formed as shown in FIG. 7B. The peripheral modification layer M1 serves as a starting point for removing the peripheral portion We in the edge trimming to be described later. The split modification layer M2 serves as a starting point for breaking the peripheral portion We to be removed into smaller pieces. In addition, a crack C develops in a thickness direction of the first wafer W from the peripheral modification layer M1 and the thickness modification layer M2 formed by the radiation of the internal laser light L2. Like the peripheral modification layer M1 and the split modification layer M2, the crack C also serves as a starting point for removing the peripheral portion We and breaking the peripheral portion We into smaller pieces. In the drawings to be referred to in the following description, illustration of the split modification layer M2 may be omitted in order to avoid complicated illustration.

A detailed method of forming the peripheral modification layer M1 in the internal modifying apparatus 60 will be explained later.

The combined wafer T in which the peripheral modification layer M1 and the split modification layer M2 are formed inside the first wafer W is then transferred to the periphery removing apparatus 70 by the wafer transfer device 40.

In the periphery removing apparatus 70, removal of the peripheral portion We of the first wafer W, that is, the edge trimming is performed, as shown in FIG. 7C. At this time, the peripheral portion We is separated from a central portion (an inner side than the peripheral portion We in the radial direction) of the first wafer W, starting from the peripheral modification layer M1, and is completely separated from the second wafer S, starting from the bonding strength reduction region R. Also, the peripheral portion We being removed is broken into smaller pieces, starting from the split modification layer M2. In removing the peripheral portion We, a blade B (see FIG. 7C) formed in, for example, a wedge shape may be inserted into the interface between the first wafer W and the second wafer S forming the combined wafer T.

The combined wafer T from which the peripheral portion We of the first wafer W has been removed is then transferred to the cleaning apparatus 80 by the wafer transfer device 40.

In the cleaning apparatus 80, the first wafer W whose peripheral portion We has been removed, and/or the second wafer S are cleaned. For example, in the cleaning apparatus 80, by radiating cleaning laser light L3 to the first wafer W and the second wafer S as illustrated in FIG. 7D, the portions irradiated with the cleaning laser light L3 may be modified and removed, so that remaining particles and the like may be removed (cleaned).

Afterwards, the combined wafer T after being subjected to all the required processes is transferred to the FOUP F on the FOUP placement table 10 by the wafer transfer device 20 via the transition device 30. In this way, the series of processes of the wafer processing in the wafer processing system 1 are completed.

Now, the detailed method of forming the bonding strength reduction region R and the peripheral modification layer M1 in the interface modifying apparatus 50 and the internal modifying apparatus 60 described above will be explained with reference to the accompanying drawings.

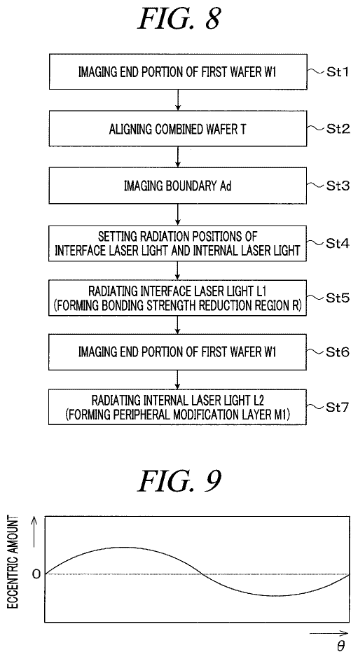

First, in the interface modifying apparatus 50, the combined wafer T held by the chuck 100 is moved to a macro imaging position. The macro imaging position is a position where the macro camera 120 is capable of imaging the outer end of the first wafer W. At the macro imaging position, while rotating the chuck 100, the macro camera 120 images the outer end of the first wafer W in 360 degrees in a circumferential direction thereof (process St1 in FIG. 8: imaging of outer end). The obtained image is outputted from the macro camera 102 to the control device 90.

The control device 90 identifies the position of the notch Wn formed in the first wafer W held by the chuck 100 and calculates an eccentric amount between a rotation center of the chuck 100 and a center of the first wafer W from the image of the macro camera 120. The eccentric amount between the rotation center of the chuck 100 and the center of the first wafer W is outputted as a waveform (sine curve) showing a relationship between a circumferential position of the first wafer W (horizontal axis in the drawing) and the eccentric amount (vertical axis in the drawing) as illustrated in FIG. 9, for example.

Also, the control device 90 calculates a moving amount of the chuck 100 based on the calculated eccentric amount to correct a Y-axis component of the corresponding eccentric amount. The control device 90 moves the chuck 100 horizontally along the Y-axis direction based on this calculated moving amount, and moves the chuck 100 to a micro imaging position (process St2 in FIG. 8: alignment). The micro imaging position is a position where the micro camera 121 is capable of imaging the non-bonding region Ae of the first wafer W.

Next, while rotating the chuck 100, the micro camera 121 images the non-bonding region Ae in 360 degrees in the circumferential direction of the first wafer W, more specifically, the boundary Ad between the bonding region Ac and the non-bonding region Ae in 360 degrees in the circumferential direction of the first wafer W (process St3 in FIG. 8: imaging of the boundary Ad). The obtained image is outputted from the micro camera 121 to the control device 90.

In the control device 90, the radiation position of the interface laser light L1 for forming the bonding strength reduction region R and the radiation position of the internal laser light L2 for forming the peripheral modification layer M1 are set from the image of the macro camera 120 and the image of the micro camera 121 (process St4 in FIG. 8: setting of radiation position). Specifically, based on the position of the outer end of the first wafer W obtained from the image of the macro camera 120, the control device 90 sets the radiation position of the internal laser light L2 to a preset trim width (previously determined distance from the outer end), and, also, sets the bonding region Ac of the first wafer W and the second wafer S outside the corresponding radiation position of the internal laser light L2 in the radial direction as a radiation area of the interface laser light L1. In addition, in the control device 90 according to the present exemplary embodiment, when setting the radiation positions of the interface laser light L1 and the internal laser light L2, the non-bonding region Ae formed corresponding to the notch Wn at the peripheral portion We of the first wafer W is taken into consideration. In other words, at the portion where the notch Wn is not formed, the radiation position of the laser light is set to the preset trim width as stated above, whereas at the portion where the notch Wn is formed, the radiation position of the laser light is set so as to avoid the non-bonding region Ae corresponding to the notch Wn, as will be described later.

In the interface modifying apparatus 50, the radiation position of the internal laser light L2 (the formation position of the peripheral modification layer M1) is set to the preset trim width based on the position of the outer end of the first wafer W obtained from the image of the macro camera 120 in this way. However, the way to determine the radiation position of the internal laser light L2 is not limited thereto. By way of example, based on the boundary Ad obtained from the image of the micro camera 121, the radiation position of the internal laser light L2 (the formation position of the peripheral modification layer M1) may be set to coincide with the boundary Ad or to be at least inner than the boundary Ad in the radial direction.

Thereafter, in the interface modifying apparatus 50, the interface laser light L1 is radiated to the set radiation area to form the bonding strength reduction region R (process St5 in FIG. 8: formation of peripheral modification layer M1).

The combined wafer T in which the bonding strength reduction region R has been formed is then transferred to the internal modifying apparatus 60. In the internal modifying apparatus 60, the combined wafer T held by the chuck 100 is first moved to the macro imaging position, and the macro camera 120 images the outer end of the first wafer W in 360 degrees in the circumferential direction thereof (process St6 in FIG. 8: imaging of outer end). The obtained image is outputted to the control device 90 from the macro camera 120.

The control device 90 identifies the position of the notch Wn formed at the first wafer W held by the chuck 100 from the image of the macro camera 120, and, also, calculates an eccentric amount between the rotation center of the chuck 100 and the center of the first wafer W.

In the internal modifying apparatus 60, while correcting the eccentric amount between the rotation center of the chuck 100 and the center of the first wafer W by moving the chuck 100 horizontally based on the calculated eccentric amount to correct a Y-axis component of the corresponding eccentric amount, the internal laser light L2 is radiated to the first wafer W along the set radiation position to thereby form the peripheral modification layer M1 (process St7 in FIG. 8: formation of peripheral modification layer M1).

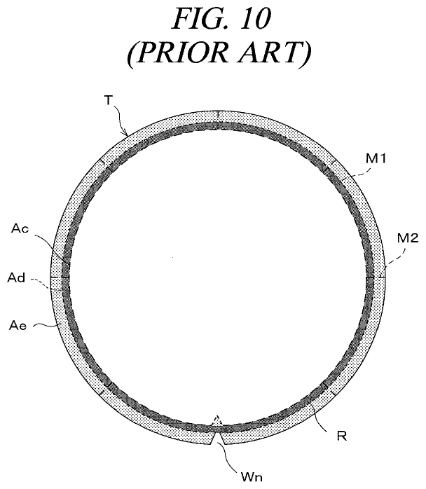

Here, in the conventional edge trimming, the radiation positions of the interface laser light L1 and the internal laser light L2 may be determined to be concentric circles spaced apart from the outer end of the first wafer W at required distances around the entire circumference of the first wafer W. In other words, in the conventional edge trimming, the peripheral portion We may be removed in a preset trim width without taking into account the non-bonding Ae formed corresponding to the notch Wn that is formed at the first wafer W. In this case, however, the bonding strength reduction region R and the peripheral modification layer M1 are formed in the non-bonding region Ae at the portion corresponding to the notch Wn, as shown in FIG. 10. As a result, the non-bonding region Ae may remain on the combined wafer T after being subjected to the edge trimming and may cause chipping in a subsequent process.

As a resolution, in the wafer processing according to the present exemplary embodiment, the bonding strength reduction region R and the peripheral modification layer M1, which will serve as the starting points for the separation of the peripheral portion We in the edge trimming, are formed in consideration of the non-bonding region Ae corresponding to the notch Wn formed at the first wafer W. Below, a detailed method of setting the radiation positions of the interface laser light L1 and the internal laser light L2 will be explained based on the following first to third patterns A to C.

### First Pattern A: Center Shift

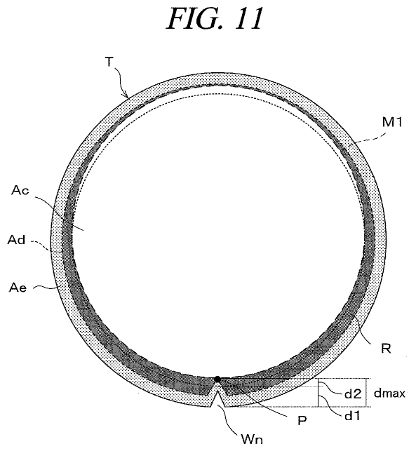

In the first pattern A, an edge position of the first wafer W on the chuck 100 is first identified from the image of the macro camera 120. Then, the position of the non-bonding region Ae formed at the position corresponding to the notch Wn, which is obtained from, for example, information previously acquired by inspection during the bonding of the first wafer W and the second wafer S and stored in the storage of the control device 90, or obtained from the image of the micro camera 121, is identified in 360 degrees in the circumferential direction of the first wafer W. Also, a portion of the non-bonding region Ae with the largest width in the radial direction (hereinafter, referred to as “reference point P”: see FIG. 11) is identified based on the outer end of the portion where the notch Wn is not formed. In other words, the reference point P, which is the position of the non-bonding portion (non-bonding region Ae) located at the innermost side corresponding to the notch Wn in the radial direction of the first wafer W, is identified from the information acquired in advance or the information acquired by imaging with the camera. Here, the information acquired in advance by the inspection during the bonding of the first wafer W and the second wafer S may be inputted to the storage of the control device 90 by an operator, or may be inputted to the storage of the control device 90 from an inspection device via a host computer in a factory, etc.

Subsequently, in the first pattern A, as illustrated in FIG. 11, the center position of a formation circle of the peripheral modification layer M1 which is to be formed concentrically with the first wafer W when viewed from the top is moved (shifted) from the center position of the first wafer W, thereby suppressing the peripheral modification layer M1 from being formed in the non-bonding region Ae outer than the boundary Ad in the radial direction.

More specifically, based on a trim width d1 which is a removal width of the peripheral portion We determined in advance according to the purpose of the wafer processing, a distance d2 from the trim width d1 to the reference point P is first calculated. The distance d2 can be calculated as, for example, a difference between the trim width d1 and a distance dmax from the outer end of the first wafer W to the reference point P, which is acquired in advance or obtained from the image of the micro camera 121.

The calculated distance d2 is set as a shift amount of the center position of the formation circle of the peripheral modification layer M1 with respect to the center of the first wafer W, and the radiation position of the internal laser light L2 (the formation position of the peripheral modification layer M1) onto the first wafer W is shifted by the distance d2 in an opposite direction from the formation position of the notch Wn in the radial direction of the first wafer W.

In the present exemplary embodiment, by shifting the radiation position of the internal laser light L2 (the formation position of the peripheral modification layer M1) by the distance d2 in this manner, it can be at least suppressed that the peripheral modification layer M1 is formed in the non-bonding region Ae.

However, in this case, on the side opposite to the formation portion of the notch Wn in the circumferential direction of the first wafer W toward which the formation circle of the peripheral modification layer M1 has been shifted, the trim width of the peripheral portion We becomes smaller than a preset value, as shown in FIG. 11.

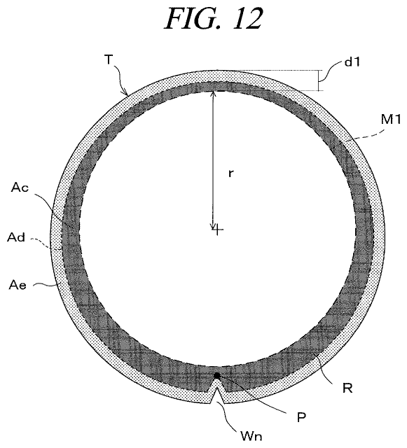

In view of this, in the present exemplary embodiment, after shifting the radiation position of the internal laser light L2 (the formation position of the peripheral modification layer M1) in this way, it is desirable to reduce a diameter r of the formation circle of the peripheral modification layer M1 as shown in FIG. 12 so that the removal width of the peripheral portion We on the side opposite to the formation portion of the notch Wn becomes the preset trim width d1.

Also, in the control device 90, the position where the center of the formation circle is shifted and the diameter r of the formation circle is reduced in this way is determined as the radiation position of the internal laser light L2 (the formation position of the peripheral modification layer M1).

In addition, the bonding region Ac outside the determined radiation position of the internal laser light L2 in the radial direction is determined as a radiation position of the interface laser light L1 (the formation area of the bonding strength reduction region R) (process St4 in FIG. 8: see FIG. 12).

Then, in the interface modifying apparatus 50, the interface laser light L1 is radiated to the interface between the first wafer W and the second wafer S based on the radiation area thus determined, thereby forming the bonding strength reduction region R (process St5 in FIG. 8). Further, in the internal modifying apparatus 60, the internal laser light L2 is radiated along the radiation position thus determined, thereby forming the peripheral modification layer M1 (process St7 in FIG. 8).

According to the first pattern A of the present exemplary embodiment, the formation circle of the peripheral modification layer M1 (chuck 100) is horizontally moved (center shifted) so that at least the specified reference point P coincides with or is at least outside the formation circle of the peripheral modification layer M1. Therefore, as shown in FIG. 11, the formation of the peripheral modification layer M1 in the non-bonding region Ae can be appropriately suppressed.

Further, by further reducing the diameter r of the formation circle of the peripheral modification layer M1, it is possible to suppress the peripheral modification layer M1 from being formed in the non-bonding region Ae, while suppressing deterioration in the quality of the edge trimming by removing the peripheral portion We more than at least the set trim width.

In the example shown in FIG. 11, the radiation position of the internal laser light L2 is moved horizontally by as much as the distance d2 from the trim width d1 to the reference point P. As mentioned above, however, the non-bonding portion of the first wafer W and the second wafer S may be formed at the inner side in the radial direction than the non-bonding region Ae corresponding to the chamfered portion of the first wafer W.

In view of this, it is desirable to set the shift amount of the radiation position of the internal laser light L2 to be slightly larger than the distance d2 from the trim width d1 to the reference point P. Also, in the case where the formation area of the bonding strength reduction region R is determined in advance, it is desirable not to radiate the internal laser light L2 to at least the bonding strength reduction region R.

In the above-described method, both the radiation area of the interface laser light L1 (the formation area of the bonding strength reduction region R) and the radiation position of the internal laser light L2 (the formation position of the peripheral modification layer M1) are determined in the process St4. However, the timing for determining the formation position of the peripheral modification layer M1 is not limited thereto. By way of example, the formation position of the bonding strength reduction region R may be specified by the micro camera 121 of the internal modifying apparatus 60, and the radiation position of the internal laser light L2 (the formation position of the peripheral modification layer M1) may be determined along the innermost periphery of the specified bonding strength reduction region R.

### Second Pattern B: Ellipse Formation

In the second pattern B, the edge position of the first wafer W and the position of the reference point P are first identified by the same method as in the first pattern A.

Then, in the second pattern B, in order to set the amount of removal of the peripheral portion We of the first wafer W by the edge trimming (the area of the region outer than the peripheral modification layer M1 in the radial direction) to be at least smaller than that in the first pattern A, the peripheral modification layer M1 is formed concentrically with the first wafer W in at least a part of a semicircular region on the side where the notch Wn is not formed (for example, within a range of ±90 degrees in the circumferential direction with respect to the oppositive side from the formation position of the notch Wn) so that the set trim width is achieved, and the peripheral modification layer M1 is formed in an elliptical shape when viewed from the top in the semicircular region in the circumferential direction of the first wafer W on the side where the notch Wn is formed (for example, within a range of ±90 degrees in the circumferential direction with respect to the notch Wn).

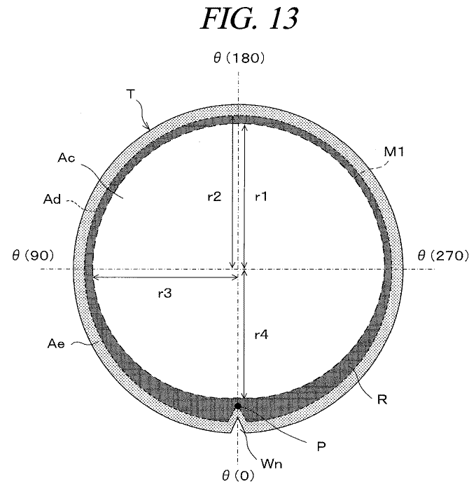

More specifically, in at least a part of the semicircular region in the circumferential direction of the first wafer W on the side where the notch Wn is not formed (in the example of FIG. 13, a range including θ(90) to θ(270) clockwise when the notch Wn is set as a reference θ(0)), the radiation position of the internal laser light L2 (the formation position of the peripheral modification layer M1) concentric with the first wafer W is first set (process St4 in FIG. 8). At this time, a diameter r1 of the peripheral modification layer M1 formed to be concentric with the first wafer W is set to be slightly smaller than a distance r2 from the center of the first wafer W to the boundary Ad, taking into account the non-bonding portion that may be formed at an inner side than the non-bonding region Ae in the radial direction (see FIG. 13).

Subsequently, in at least a part of the semicircular region in the circumferential direction of the first wafer W on the side where the notch Wn is formed (in the example of FIG. 13, a range including θ(90) to θ(270) counterclockwise), the radiation position of the internal laser light L2 (the formation position of the peripheral modification layer M1) is set in an elliptical shape having a short side from the center of the first wafer W toward the formation position of the notch Wn (process St4 in FIG. 8). At this time, a shorter diameter r4 of the peripheral modification layer M1 formed in the elliptical shape is set to be smaller than the aforementioned diameter r1 in consideration of the notch Wn so that a longer diameter r3 of the peripheral modification layer M1 is equal to the aforementioned diameter r1 (see FIG. 13). More specifically, the radiation position of the internal laser light L2 is set so that the reference point P coincides with the formation position of the peripheral modification layer M1 or is located at an outer side than the formation position of the peripheral modification layer M1 in the radial direction.

In addition, the bonding region Ac outside the determined radiation position of the internal laser light L2 in the radial direction is determined as the radiation position of the interface laser light L1 (the formation area of the bonding strength reduction region R) (process St4 in FIG. 8: see FIG. 13).

Furthermore, the regions for distinguishing the side where the notch Wn is formed from the side where the notch Wn is not formed are not limited to the semicircular regions with boundaries of θ(90) and θ(270) as shown in FIG. 13. By way of example, the region on the side where the notch Wn is not formed, where the internal laser light L2 is radiated concentrically with the first wafer W, may be set as a sectoral region with a central angle larger or smaller than 180 degrees, and the internal laser light L2 may be radiated concentrically with the first wafer W in this sectoral region.

At this time, the larger the central angle of the sectorial region in which the internal laser light L2 is radiated concentrically with the first wafer W, the smaller the amount of removal of the peripheral portion We of the first wafer W may be.

In the interface modifying apparatus 50, while correcting the eccentric amount between the center of rotation of the chuck 100 and the center of the first wafer W obtained from the imaging result from the macro camera 120 in the process St1, more specifically, while rotating the chuck 100 around the vertical axis while concurrently moving the chuck 100 horizontally so as to cancel the sine curve component of the waveform shown in FIG. 9, the interface laser light L1 is radiated to the interface between the first wafer W and the second wafer S based on the set radiation area to thereby form the bonding strength reduction region R (process St5 in FIG. 8). Further, in the internal modifying apparatus 60, while moving the chuck 100 horizontally so as to cancel the sine curve component of the waveform shown in FIG. 9, the internal laser light L2 is radiated along the determined radiation position to thereby form the peripheral modification layer M1 (process St7 in FIG. 8).

According to the second pattern B of the present exemplary embodiment, in the circumferential direction of the first wafer W, on the side where the notch Wn is not formed, the peripheral modification layer M1 is formed concentrically with the first wafer W, so that the trim width can be reduced and the yield can be improved. On the side where the notch Wn is formed, on the other hand, the peripheral modification layer M1 is formed in the elliptical shape, so that the occurrence of the chipping in the subsequent process can be suppressed.

Besides, by forming the bonding strength reduction region R and the peripheral modification layer M1 while moving the chuck 100 horizontally so as to correct the eccentricity of the center of the first wafer W with respect to the rotation center of the chuck 100, the bonding strength reduction region R and the peripheral modification layer M1 can be appropriately suppressed from being formed in the non-bonding region Ae.

### Third Pattern C: Formation Avoiding Notch Wn

In the third pattern C, the edge position of the first wafer W and the position of the reference point P are first identified by the same method as in the first pattern A and the second pattern B.

Subsequently, in the third pattern C, in order to further reduce the amount of removal of the peripheral portion We of the first wafer W by the edge trim (the area of the region outer than the peripheral modification layer M1 in the radial direction) as compared to that in the second pattern B, the bonding strength reduction region R and the peripheral modification layer M1 are formed so as to avoid the non-bonding region Ae only at the portion where the notch Wn is formed, and the peripheral modification layer M1 is formed concentrically with the first wafer W so as to have the set trim width at the portion where the notch Wn is not formed.

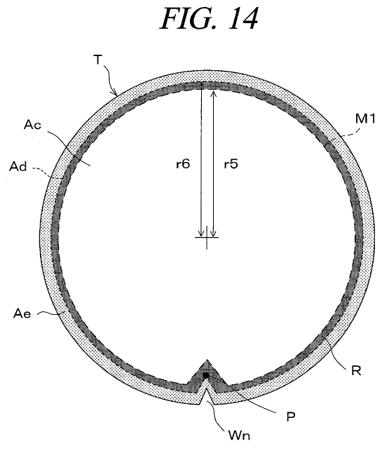

First, at the portion of the first wafer W in the circumferential direction where the notch Wn is not formed, the radiation position of the internal laser light L2 (the formation position of the peripheral modification layer M1) concentric with the first wafer W is set in a trim width previously determined according to the purpose of the wafer processing (process St4 in FIG. 8). At this time, a diameter r5 of the peripheral modification layer M1 formed to be concentric with the first wafer W is set to be slightly smaller than a distance r6 from the center of the first wafer W to the boundary Ad, taking into account the non-bonding portion that may be formed at an inner side than the non-bonding region Ae in the radial direction (see FIG. 14).

Then, the radiation shape of the internal laser light L2, when viewed from the top, at the portion where the notch Wn is formed is set such that the specified reference point P at least coincides with the formation position of the peripheral modification layer M1 or is outside the formation position of the peripheral modification layer M1 at the formation portion of the notch Wn in the circumferential direction of the first wafer W (process St4 in FIG. 8). Specifically, in the example shown in FIG. 14, the radiation shape of the internal laser light L2, when viewed from the top, is set to be an approximate triangle along the outline of the shape (approximately triangle) of the notch Wn formed at the first wafer W.

In addition, the bonding region Ac outside the radiation position of the internal laser light L2 in the radial direction is determined as the radiation position of the interface laser light L1 (the formation area of the bonding strength reduction region R) (process St4 in FIG. 8: see FIG. 14).

In addition, the radiation shape of the internal laser light L2 viewed from the top is not limited to the shape that matches the outline of the notch Wn shown in FIG. 14, but can be set arbitrarily as long as the reference point P at least coincides with or is outside the formation position of the peripheral modification layer M1.

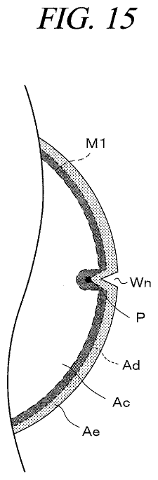

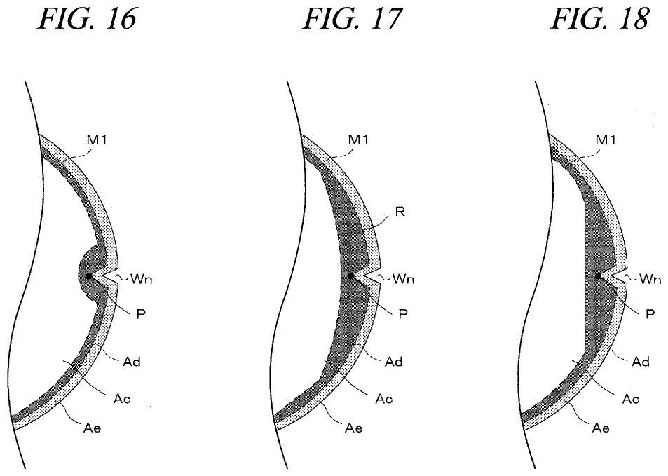

As specific examples, the radiation shape of the internal laser light L2 may be set to be a substantially ellipse at the portion where the notch Wn is formed, as shown in FIG. 15, may be set to be a circular arc that gently curves toward the radially inside of the first wafer W, as shown in FIG. 16, or may be set to be a circular arc that gently curves toward the radially outside of the first wafer W, as shown in FIG. 17.

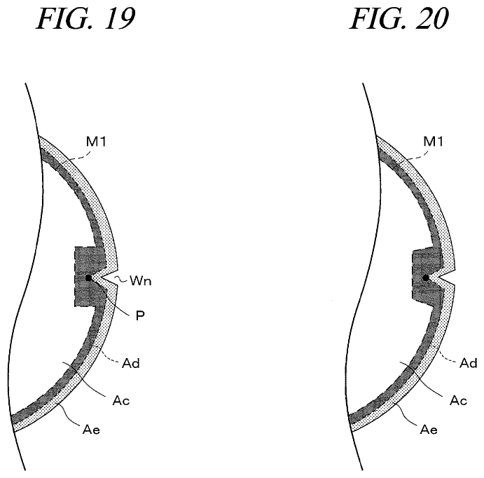

Alternatively, the radiation shape of the internal laser light L2 at the portion where the notch Wn is formed may be set to a linear shape (so-called orientation flat shape), as shown in FIG. 18, or may be set to a rectangle as shown in FIG. 19. Still alternatively, the radiation shape of the internal laser light L2 may be set to a trapezoid having a slope in a radial direction from the center of the first wafer W. Here, the radial direction from the center of the first wafer W is the same direction as the formation direction of the split modification layer M2 formed in the internal modifying apparatus 60.

In the interface modifying apparatus 50, by radiating the interface laser light L1 to the interface between the first wafer W and the second wafer S based on the set radiation area while correcting the eccentric amount between the center of rotation of the chuck 100 and the center of the first wafer W obtained from the imaging result from the macro camera 120 in the process St1, more specifically, while moving the chuck 100 horizontally so as to cancel the sine curve component of the waveform shown in FIG. 9, thereby forming the bonding strength reduction region R (process St5 in FIG. 8). Also, in the internal modifying apparatus 60, by radiating the internal laser light L2 toward the first wafer W along the set radiation shape while moving the chuck 100 horizontally so as to cancel the sine curve component of the waveform shown in FIG. 9, the peripheral modification layer M1 is formed (process St7 in FIG. 8). The method of correcting the eccentricity between the rotation center of the chuck 100 and the center of the first wafer W is the same as that in the second pattern B described above.

Here, the formation of the peripheral modification layer M1 concentric with the first wafer W for the portion where the notch Wn is not formed, and the formation of the peripheral modification layer M1 in any of the aforementioned shapes for the portion where the notch Wn is formed may be performed continuously in a so-called one-stroke manner, or may be performed independently in two separate stages.

### When Continuously Forming the Peripheral Modification Layer M1

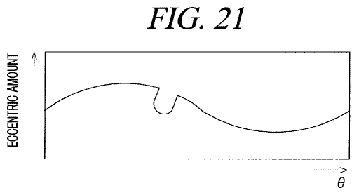

When continuously performing the formation of the peripheral modification layer M1 at the portion where the notch Wn is not formed and the formation of the peripheral modification layer M1 at the portion where the notch Wn is formed, the radiation shape of the internal laser light L2 set for the portion where the notch Wn is formed (the elliptical shape corresponding to FIG. 15, in the example shown in FIG. 21) is superimposed, in accordance with the position (angle) of the notch Wn in the circumferential direction, on the waveform (see FIG. 9) that is created to correct the eccentric amount between the rotation center of the chuck 100 and the center of the first wafer W, so that a composite waveform as shown in FIG. 21 is generated. Then, the peripheral modification layer M1 is formed inside the first wafer W using the composite waveform thus generated.

Specifically, at the portion where the notch Wn is not formed, while rotating the chuck 100 around the vertical axis and also moving the chuck 100 horizontally (correcting the eccentricity between the rotation center of the chuck 100 and the center of the first wafer W) so as to cancel a sine curve component of the composite waveform (the eccentric amount between the rotation center of the chuck 100 and the center of the first wafer W), the internal laser light L2 is radiated concentrically with the first wafer W.

In addition, at the portion where the notch Wn is formed, the internal laser light L2 is radiated while moving the chuck 100 and the laser head 110 relative to each other in the horizontal direction so as to avoid the non-bonding region Ae at the portion where the notch Wn is formed, more specifically so that the specified reference point P is located at the outer side than the radiation position of the internal laser light L2 in the radial direction. At this time, the chuck 100 may be rotated around the vertical axis in accordance with the radiation shape of the internal laser light L2, or the rotation thereof may be stopped.

The same applies to the formation of the bonding strength reduction region R. In other words, the bonding strength reduction region R may be formed continuously without interruption in the portion where the notch Wn is formed and the portion where the notch Wn is not formed, as stated above.

### When Forming the Peripheral Modification Layer M1 in Two Stages

Meanwhile, when performing the formation of the peripheral modification layer M1 at the portion where the notch Wn is not formed and the formation of the peripheral modification layer M1 at the portion where the notch Wn is formed in two separate stages, the composite waveform (see FIG. 21) is first generated by superimposing the set radiation shape of the internal laser light L2, in the same way as in the case of forming the peripheral modification layer M1 continuously.

Then, while rotating the chuck 100 around the vertical axis and also moving the chuck 100 horizontally (to correct the eccentricity between the rotation center of the chuck 100 and the center of the first wafer W) so as to cancel the sine curve component of the composite waveform (the eccentric amount between the rotation center of the chuck 100 and the center of the first wafer W), the internal laser light L2 is radiated to the portion where the notch Wn is not formed, concentrically with the wafer W.

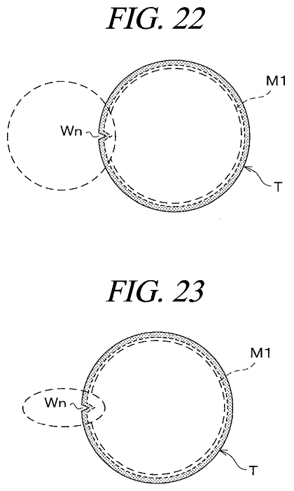

Once the peripheral modification layer M1 is formed at the portion where the notch Wn is not formed, the chuck 100 is then moved to a position for forming the peripheral modification layer M1 at the portion where the notch Wn is formed. As shown in FIG. 22 and FIG. 23, the radiation shape of the internal laser light L2 for generating the composite waveform can be generated by superimposing a circle or an ellipse having a rotation axis different from that of the first wafer W, for example. From this point of view, when forming the peripheral modification layer M1 in the portion where the notch Wn is formed, the chuck 100 (the first wafer W) is moved so that the rotation center of the chuck 100 coincides with the rotation axis of the circle or the ellipse that is superimposed to generate the composite waveform, and the internal laser light L2 is radiated to the inside of the first wafer W while rotating the chuck 100 around the vertical axis at a position for forming the peripheral modification layer M1 in the portion where the notch Wn is formed.

In addition, when forming the peripheral modification layer M1 in the form of an orientation flat or a rectangle as shown in FIG. 18 and FIG. 19 in the portion where the notch Wn is formed, these radiation shapes of the internal laser light L2 do not have a rotation axis as shown in FIG. 22 and FIG. 23.

In such a case, it is not necessary to move the chuck 100 to a position for forming the peripheral modification layer M1 at the portion where the notch Wn is formed, and the internal laser light L2 may be radiated to the inside of the first wafer W while simply moving the chuck 100 and the laser head 110 relative to each other in the horizontal direction.

The same applies to the formation of the bonding strength reduction region R. In other words, the formation of the bonding strength reduction region R may be performed in two separate stages for the portion where the notch Wn is formed and for the portion where the notch Wn is not formed, as described above.

According to the above third pattern C, in the circumferential direction of the first wafer W, the bonding strength reduction region R and the peripheral modification layer M1 are formed concentrically with the first wafer W in the portion where the notch Wn is not formed, and the bonding strength reduction region R and the peripheral modification layer M1 are formed to avoid the non-bonding region Ae only in the portion where the notch Wn is formed. This makes it possible to further reduce the amount of removal of the peripheral portion We as compared to the above-described second pattern B, thus improving yield.

As described above, in the first to third patterns A to C, information on the non-bonding portion including the formation position of the non-bonding region Ae (more specifically, the position of the boundary Ad) at the peripheral portion We (the formation position of the non-bonding portion where the first wafer W and the second wafer S are not bonded) may be obtained from, for example, an imaging result by a camera, and information obtained in advance outside the wafer processing system 1, for example, may be outputted to the control device 90 at the same time as the combined wafer T (FOUP F) is carried into the wafer processing system 1. This information on the non-bonding portion can be obtained in a bonding apparatus (not shown) that bonds the first wafer W and the second wafer S.

Further, in the above-described exemplary embodiment, the information on the non-bonding portion is obtained from the imaging result acquired by the camera of the internal modifying apparatus 60. However, the camera may be disposed in another apparatus of the wafer processing system 1, and the information may be obtained by taking an image by this camera. By way of example, the camera for imaging the first wafer W may be placed in, for example, the transition device 30.

In addition, in the first to third patterns A to C described above, the position of the boundary Ad between the non-bonding region Ae and the bonding region Ac, which is obtained from the imaging result by the camera, is used as the aforementioned “information on the non-bonding portion.” As state above, however, the non-bonding portion of the first wafer W and the second wafer S may also be formed at an inner side than the boundary Ad in the radial direction.

In view of this, it is desirable that the “information on the non-bonding portion” acquired prior to the formation of the peripheral modification layer M1 includes the position of the non-bonding portion located at the innermost side in the radial direction at the interface between the first wafer W and the second wafer S in the portion where the notch Wn is formed. In this case, the non-bonding portion located at the innermost side in the radial direction at the interface between the first wafer W and the second wafer S becomes the “reference point P.”

In addition, in the above-described exemplary embodiment, by forming the bonding strength reduction region R and the peripheral modification layer M1 slightly inside the boundary Ad obtained as the “information on the non-bonding portion,” the non-bonding portion that is formed at an inner side than the boundary Ad in the radial direction is included in the trim width by the edge trimming. However, by obtaining, as the “information on the non-bonding portion,” the position of the non-bonding portion located at the innermost side in the radial direction at the interface between the first wafer W and the second wafer S in the portion where the notch Wn is formed, it is possible to more appropriately suppress the non-bonding portion from being left at the interface between the first wafer W and the second wafer S after the edge trimming.

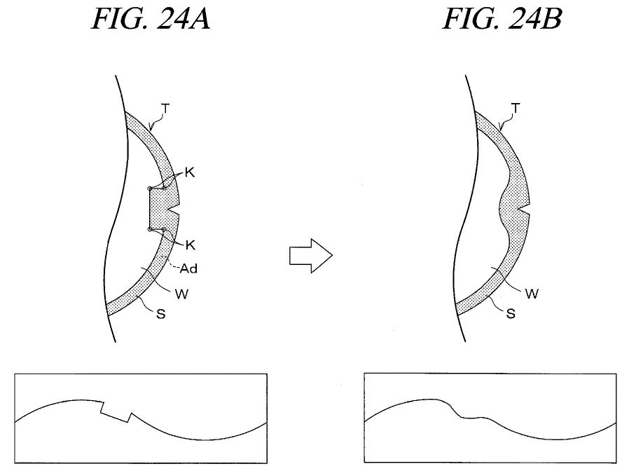

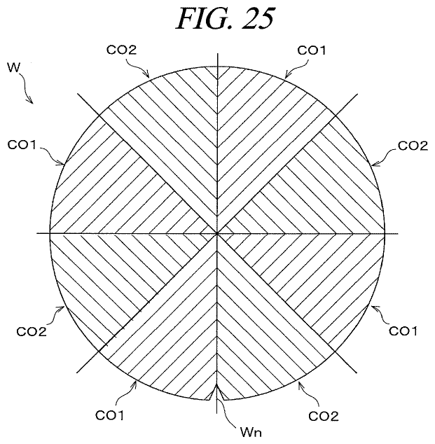

Furthermore, in the case of forming the peripheral modification layer M1 so as to avoid the notch Wn as in the third pattern C described above, if an angled portion K (see FIG. 24A) is formed at the outer end of the first wafer W from which the peripheral portion We has been removed, this angled portion K may be broken in the subsequent process, causing the chipping.

Therefore, when forming the peripheral modification layer M1 while avoiding the notch Wn, it is desirable to correct the radiation shape of the internal laser light L2 lest the angled portion K should be formed at the outer edge of the first wafer W from which the peripheral portion We has been removed. As a specific example, by performing an averaging processing on the composite waveform shown as an example in FIG. 24A, the outline of the outer edge of the first wafer W after being subjected to the removal of the peripheral portion We becomes smooth as illustrated in FIG. 24B, so that the occurrence of the chipping in the subsequent process can be suppressed.

The first wafer W in which the peripheral modification layer M1 is formed in the wafer processing system 1 according to the technology of the present disclosure has a first crystal orientation CO1 and a second crystal orientation CO2 alternately in the circumferential direction of the first wafer W, as shown in FIG. 25. The notch Wn formed at the first wafer W indicates this crystal orientation.

Therefore, in order to allow the crack C to properly develop along the crystal orientation from the peripheral modification layer M1 formed in the first wafer W in the internal modifying apparatus 60, radiation conditions such as the incident direction of the internal laser light L2 and the focal point shape (longitudinal direction of the focal point) of the internal laser light L2 need to be determined in consideration of this crystal orientation.

To elaborate, when forming the peripheral modification layer M1 concentrically with the first wafer W, the radiation conditions of the internal laser light L2 are changed according to the crystal orientation (the first crystal orientation CO1 or the second crystal orientation CO2) shown in FIG. 25.

Meanwhile, when forming the peripheral modification layer M1 so as to avoid the notch Wn as in the third pattern C described above, the relative radiation angle of the internal laser light L2 with respect to the crystal orientation of the first wafer W changes according to the radiation shape of the internal laser light L2 (the radiation position of the internal laser light L2) viewed from the top. Therefore, in the portion where the notch Wn is formed, the radiation conditions of the internal laser light L2 are changed, further taking into consideration the trim shape of the peripheral portion We (the radiation shape of the internal laser light L2 when viewed from the top) in addition to the crystal orientation (the first crystal orientation CO1 or the second crystal orientation CO2) shown in FIG. 25.

The information upon the crystal orientation of the first wafer W may be acquired concurrent with or prior to the carry-in of the combined wafer T (FOUP F) into the wafer processing system 1, for example.

Further, in the above description, the peripheral modification layer M1 and the split modification layer M2 are formed in the internal modifying apparatus 60 after the bonding strength reduction region R is formed in the interface modifying apparatus 50, as shown in FIG. 7A to FIG. 7D. However, the order of the substrate processing in the wafer processing system 1 is not limited thereto. That is, the bonding strength reduction region R may be formed in the interface modifying apparatus 50 after the peripheral modification layer M1 and the split modification layer M2 are formed in the internal modifying apparatus 60.

In this case, the radiation area of the interface laser light L1 for forming the bonding strength reduction region R (the formation area of the bonding strength reduction region R) may be set based on the position of the peripheral modification layer M1 formed in the internal modifying apparatus 60, as stated above.

Though the above exemplary embodiment has been described for the case where formation of the non-bonding region Ae is formed in the combined wafer T in which the first wafer W and the second wafer S are bonded. However, the first wafer W and the second wafer S may be bonded to form the combed wafer after the non-bonding region Ae is formed in the first wafer W or the second wafer S before being bonded to each other.

In this case, a laser processing or an etching processing such as wet etching may be adopted to form the non-bonding region Ae.

In addition, in the above exemplary embodiment, if the non-bonding region Ae is formed at the inner side than the non-bonding portion at the notch Wn in the first wafer W, the formation position of the peripheral modification layer M1 may be determined based on the information on the non-bonding portion described above, in accordance with the non-bonding region Ae at the innermost side.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

### EXPLANATION OF CODES

1: Wafer processing system
60: Internal modifying apparatus
70: Periphery removing apparatus
90: Control device
Ac: Bonding region
Ae: Non-bonding region
L2: Internal laser light
M1: Peripheral modification layer
S: Second wafer
T: Combined wafer
W: First wafer
Wc: Central portion
We: Peripheral portion
Wn: Notch

1. A substrate processing method of processing a combined substrate in which a first substrate and a second substrate are bonded,
wherein the first substrate comprises:
a notch formed by cutting out a part of a peripheral portion of the first substrate to be removed;
a bonding portion bonded to the second substrate; and
a non-bonding portion not bonded to the second substrate,
the substrate processing method comprises:
forming a peripheral modification layer serving as a starting point for separation of the peripheral portion by radiating laser light along a boundary between the peripheral portion of the first substrate and a central portion of the first substrate; and
separating the peripheral portion from the combined substrate, starting from the peripheral modification layer, and
in the forming of the peripheral modification layer, a formation position of the peripheral modification layer corresponding to a portion where the notch is formed is determined based on information of the non-bonding portion.

2. The substrate processing method of claim 1,
wherein the information of the non-bonding portion includes a position of a reference point which is located, in the non-bonding portion, at an innermost side in a radial direction of the first substrate in the portion where the notch is formed, and
a center position of a formation circle of the peripheral modification layer, which is formed in a circular shape when viewed from a top, is shifted so that the reference point is located at least outside the formation circle.

3. The substrate processing method of claim 2,
wherein a diameter of the formation circle is reduced based on a previously determined removal width of the peripheral portion at a position opposite from the portion where the notch is formed.

4. The substrate processing method of claim 1, further comprising:
forming the peripheral modification layer to be a concentric circle with the first substrate when viewed from a top, in at least a part of a semicircular region of the first substrate on a side where the notch is not formed; and
forming the peripheral modification layer in an elliptical shape having a short side from a center of the first substrate to a formation position of the notch when viewed from the top, in at least a part of a semicircular region of the first substrate on a side where the notch is formed.

5. The substrate processing method of claim 4,
wherein the information of the non-bonding portion includes a position of a reference point which is located, in the non-bonding portion, at an innermost side in a radial direction of the first substrate in the portion where the notch is formed,
a longer diameter of the elliptical shape is set to a same length as a diameter of the concentric circle in the semicircular region on the side where the notch is not formed, and
a shorter diameter of the elliptical shape is set to be smaller than a distance from the center of the first substrate to the reference point.

6. The substrate processing method of claim 1,
wherein the information of the non-bonding portion includes a position of a reference point which is located, in the non-bonding portion, at an innermost side in a radial direction of the first substrate in the portion where the notch is formed, and
the substrate processing method further comprises:
forming the peripheral modification layer concentrically with the first substrate when viewed from a top, in a portion of the first substrate in a circumferential direction where the notch is not formed; and
forming the peripheral modification layer in a shape conforming the non-bonding portion formed corresponding to the notch when viewed from the top, in a portion of the first substrate in the circumferential direction where the notch is formed.

7. The substrate processing method of claim 6,
wherein the peripheral modification layer in the portion where the notch is not formed and the peripheral modification layer in the portion where the notch is formed are continuously formed.

8. The substrate processing method of claim 6,
wherein the peripheral modification layer in the portion where the notch is not formed and the peripheral modification layer in the portion where the notch is formed are formed independently in two separate stages.

9. The substrate processing method of claim 6, further comprising:
superimposing a waveform indicating a correlation of an eccentric amount between a center of the first substrate and a rotation center of a substrate holder holding the combined substrate with respect to the circumferential direction of the first substrate, and a forming shape of the peripheral modification layer, when viewed from the top, for the portion where the notch is formed, thereby generating a composite waveform indicating the formation position of the peripheral modification layer on the first substrate; and
performing an averaging processing on the generated composite waveform.

10. The substrate processing method of claim 6, further comprising:
determining conditions of radiating the laser light to the first substrate in consideration of crystal orientation of the first substrate and a forming shape of the peripheral modification layer, when viewed from the top, for the portion where the notch is formed.

11. The substrate processing method of claim 1, further comprising:
radiating second laser light to an interface between the first substrate and the second substrate to form a bonding strength reduction region in which bonding strength between the first substrate and the second substrate is reduced,
wherein a formation position of the bonding strength reduction region corresponding to the portion where the notch is formed is determined based on the information of the non-bonding portion.

12. The substrate processing method of claim 1, further comprising:
acquiring the information of the non-bonding portion by imaging the combined substrate held by a substrate holder.

13. A substrate processing system configured to process a combined substrate in which a first substrate and a second substrate are bonded,
wherein the first substrate comprises:
a notch formed by cutting out a part of a peripheral portion of the first substrate to be removed;
a bonding portion bonded to the second substrate; and
a non-bonding portion not bonded to the second substrate,
the substrate processing system comprises:
an internal modifying apparatus configured to radiate laser light along a boundary between the peripheral portion of the first substrate and a central portion of the first substrate to form a peripheral modification layer serving as a starting point for separation of the peripheral portion;
a periphery removing apparatus configured to separate the peripheral portion from the combined substrate, starting from the peripheral modification layer; and
a control device, and
when forming the peripheral modification layer, the control device is configured to determine, based on information of the non-bonding portion, a formation position of the peripheral modification layer corresponding to a portion where the notch is formed.

14. The substrate processing system of claim 13,
wherein the internal modifying apparatus comprises:
a substrate holder configured to hold the combined substrate;
a laser radiating device configured to radiate the laser light; and
a camera configured to image the combined substrate held by the substrate holder, and
the control device is configured to control an operation of the internal modifying apparatus so that the information of the non-bonding portion is acquired by imaging the combined substrate held by the substrate holder.

15. The substrate processing system of claim 13, further comprising:
an interface modifying apparatus configured to radiate second laser light to an interface between the first substrate and the second substrate to form a bonding strength reduction region in which bonding strength between the first substrate and the second substrate are reduced,
wherein when forming the bonding strength reduction region, the control device is configured to determine, based on the information of the non-bonding portion, a formation position of the bonding strength reduction region corresponding to the portion where the notch is formed.

16. The substrate processing system of claim 13,
wherein the information of the non-bonding portion includes a position of a reference point which is located, in the non-bonding portion, at an innermost side in a radial direction of the first substrate in the portion where the notch is formed,
when forming the peripheral modification layer, the control device is configured to shift a center position of a formation circle of the peripheral modification layer, which is formed in a circular shape when viewed from a top, so that the reference point is located at least outside the formation circle.

17. The substrate processing system of claim 13,
wherein when forming the peripheral modification layer, the control device is configured to:
form the peripheral modification layer concentrically with the first substrate when viewed from a top, in at least a part of a semicircular region of the first substrate on a side where the notch is not formed; and
form the peripheral modification layer in an elliptical shape having a short side from a center of the first substrate to a formation position of the notch when viewed from the top, in at least a part of a semicircular region of the first substrate on a side where the notch is formed.

18. The substrate processing system of claim 13,
wherein the information of the non-bonding portion includes a position of a reference point which is located, in the non-bonding portion, at an innermost side in a radial direction of the first substrate in the portion where the notch is formed, and
the control device is configured to:
form the peripheral modification layer concentrically with the first substrate when viewed from a top, in a portion of the first substrate in a circumferential direction where the notch is not formed; and
form the peripheral modification layer in a shape conforming the non-bonding portion formed corresponding to the notch when viewed from the top, in a portion of the first substrate in the circumferential direction where the notch is formed.
